(19) United States
(12) Patent Application Publication
(10) Pub. No.: US 2018/0300175 A1
(43) Pub. Date: Oct. 18, 2018

(54) GATE ARRAY ARCHITECTURE WITH SCALABLE TRANSISTOR SIZE

(71) Applicants: Jonathan Park, San Jose, CA (US); Yin Hoa Liew, Penang (MY); Wei Zhi Kang, Penang (MY); Yan Khai Lee, Penang (MY); Wan Tat, Penang (MY); Toong Erh Ooi, Penang (MY); Soo Chuan Tan, Penang (MY)

(72) Inventors: Jonathan Park, San Jose, CA (US); Yin Hoa Liew, Penang (MY); Wei Zhi Kang, Penang (MY); Yan Khai Lee, Penang (MY); Wan Tat, Penang (MY); Toong Erh Ooi, Penang (MY); Soo Chuan Tan, Penang (MY)

(21) Appl. No.: 14/541,421

(22) Filed: Nov. 14, 2014

Related U.S. Application Data
(63) Continuation of application No. 14/505,875, filed on Oct. 3, 2014, now Pat. No. 9,183,050.

(51) Int. Cl. G06F 9/48; G06F 9/50

(52) U.S. Cl. CPC G06F 9/4887; G06F 9/505; G06F 9/5011

(57) ABSTRACT

A base cell of a gate array architecture includes an increased number of transistors that can be interconnected or not interconnected so as to realize similar advantages as a having a library of transistors of different sizes. In one embodiment, each column a base cell contains two PMOS transistors and two NMOS transistors connected so as to share a single polysilicon (“poly”) gate electrode. Such an arrangement of the transistors in metal only programmable base cell architecture provides three different P and N transistor widths per poly gate and may provide nine different combinations transistor widths for P and N for design. The number of gate electrodes is minimized and their arrangement simplified such that the size of the base cell may be same size compared to traditional gate array base cell with four transistors. Moreover, only a single type of base cell need be provided, simplifying layout and design.

### BACKGROUND

In a typical gate array architecture, the transistor size is fixed. Trade-offs have to be made between factors such as performance, area, power, balanced delay between rise and fall times, etc. when determining the size of the transistor used in the gate array architecture.

For example, when creating a D Flip-Flip cell using a gate array architecture, all the transistors size are the same. Typically, a feedback tri-state buffer in a D Flip-flop circuit does not require a large transistor width, but due to the gate array architecture, it uses the same transistor size as the rest of the circuit. A penalty results in terms of higher leakage and switching power.

A known base cell architecture, described in U.S. Pat. No. 8,533,641 of the present assignee, incorporated herein by reference, is illustrated in FIG. 1A and FIG. 1B, showing layout and schematic views, respectively. In an exemplary embodiment, the base cell includes four transistors—two PMOS transistors having the same width and two NMOS transistors having the same width. The base cell may contain six or more MOS transistors in other embodiments. Transistors MPL and MPR are left and right PMOS transistors and are connected by a common a drain node PM. The source node of the left PMOS transistor MPL is labeled PL and the source node of the right PMOS transistor MPR is labeled PR. Similarly transistors MNL and MNR are right and left NMOS transistors and have a common drain node NM. The source node of the left NMOS transistor MPL is labeled NL and the source node of the right NMOS transistor MNR is labeled NR. A node PB, which is a body node for PMOS transistors, and a node NB, which is a body nodes for NMOS transistors, are also illustrated. The gates of the transistors MPL and MNL transistors are connected by a common gate electrode labeled GL. Similarly gates of the transistors MPR and MNR are connected by a common gate electrode labeled GR.

The known base cell architecture only provides for transistors of a single size. As a result, signal drive strengths, rise times and fall times, and power consumption cannot be adjusted readily.

Base cell architectures that incorporate transistors of different sizes are known from U.S. Pat. Nos. 5,289,021, 5,055,716 and 5,038,192. These base cell architectures incorporates more transistors of different sizes to overcome the deficiency of traditional conventional gate array with single transistor sizes such as FIGS. 1A and 1B. However, these base cell architectures have different arrangements of gate electrodes and connections to sources and drains of different transistors to provide more flexibility for optimization of performance and power but resulting much larger base cell size. For example the base cell architecture of U.S. Pat. No. 5,289,021 has total of 8 transistors and the transistors and connection of gate electrodes is shown in FIG. 9 of the patent which shows the height of the proposed base cell is much taller resulting much larger base cell to provide more efficient sequential cells such as latches, flip flops etc. However this base architecture is not optimum for creating inverter and buffer cells to have large drive hence it propose to have different base cell which is similar to traditional 4 transistors base cell. This embodiment of having two different base cells, one with 8 transistors and the other with 4 transistors leads to complexity for the arrangement of two different base cells and its usability.

As will be described in more detail below, the preferred embodiment of new base cell with multiple size transistors but same size as the traditional four transistors base cell will provide improvements in power and performance optimization and more efficient than prior art base cells.

### BRIEF DESCRIPTION OF THE DRAWING

The present invention may be understood from the following detailed description in conjunction with the appended drawing figures. In the drawing:

FIG. 1A is a plan diagram of a known gate array base cell.

FIG. 1B is a schematic diagram of the gate array base cell of FIG. 1A.

FIG. 2A is a plan diagram of a gate array base cell having an increased number of transistors.

FIG. 2B is a plan diagram of a portion of a gate array using the base cell of FIG. 2A.

FIG. 2C is a plan diagram illustrating identical sizing of the gate array base cells of FIGS. 1A and 2A in accordance with one embodiment.

FIG. 3A is a plan diagram of a small-sized PMOS transistor configuration using the gate array base cell of FIG. 2.

FIG. 3B is a plan diagram of a medium-sized PMOS transistor configuration using the gate array base cell of FIG. 2.

FIG. 3C is a plan diagram of a large-sized PMOS transistor configuration using the gate array base cell of FIG. 2.

FIG. 4A is a plan diagram of a NAND gate configuration using small-sized transistors.

FIG. 4B is a schematic diagram of the NAND gate of FIG. 4A.

FIG. 4C is a plan diagram of the base cell.

FIG. 5A is a plan diagram of a NAND gate configuration using medium-sized transistors.

FIG. 5B is a schematic diagram of the NAND gate of FIG. 4A.

FIG. 5C is a plan diagram of the base cell.

FIG. 6A is a plan diagram of a NAND gate configuration using large-sized transistors.

FIG. 6B is a schematic diagram of the NAND gate of FIG. 4A.

FIG. 6C is a plan diagram of the base cell.

FIG. 7A is a plan diagram of a NOR gate configuration using both small-sized and medium-sized transistors.

FIG. 7B is a schematic diagram of the NOR gate of FIG. 7A.

FIG. 7C is a plan diagram of the base cell.

FIG. 8A is a schematic diagram of a flip-flop circuit configuration of using different-sized transistors formed from base cells like that of FIG. 2A.

FIG. 8B is a layout connection diagram for the latch circuit of FIG. 8A.

### DETAILED DESCRIPTION

### Summary

A base cell of a gate array architecture includes an increased number of transistors that can be interconnected or not interconnected so as to realize similar advantages as a having a library of transistors of different sizes. In one embodiment, a base cell includes eight transistor (four PMOS and four NMOS transistors) arranged in 2×2 arrangement, where one row of the PMOS transistors has a smaller width than the other row, and one row of the NMOS transistors has a smaller width than the other row. Each column contains two PMOS transistors and two NMOS transistors. The transistors in each column may be connected so as to share a single polysilicon (“poly”) gate line. Programming of the base cell may start, for example, with a contact metal layer.

In one embodiment, such an arrangement of the transistors in metal only programmable base cell architecture provides three different P and N transistor widths per poly gate that provides flexibilities of using different transistor width in cell design to provide improvement in performance and reduction in active and leakage power.

In another embodiment, the number of gate electrodes is minimized and their arrangement simplified such that the size of the base cell may be same as the traditional four transistor base cell. Moreover, only a single type of base cell is provided, simplifying layout and design yet provides better flexibilities in cell design for performance and power optimization compared to traditional gate array base cell of 4 transistors or previous teachings of multiple transistor width base cell architecture.

### Description

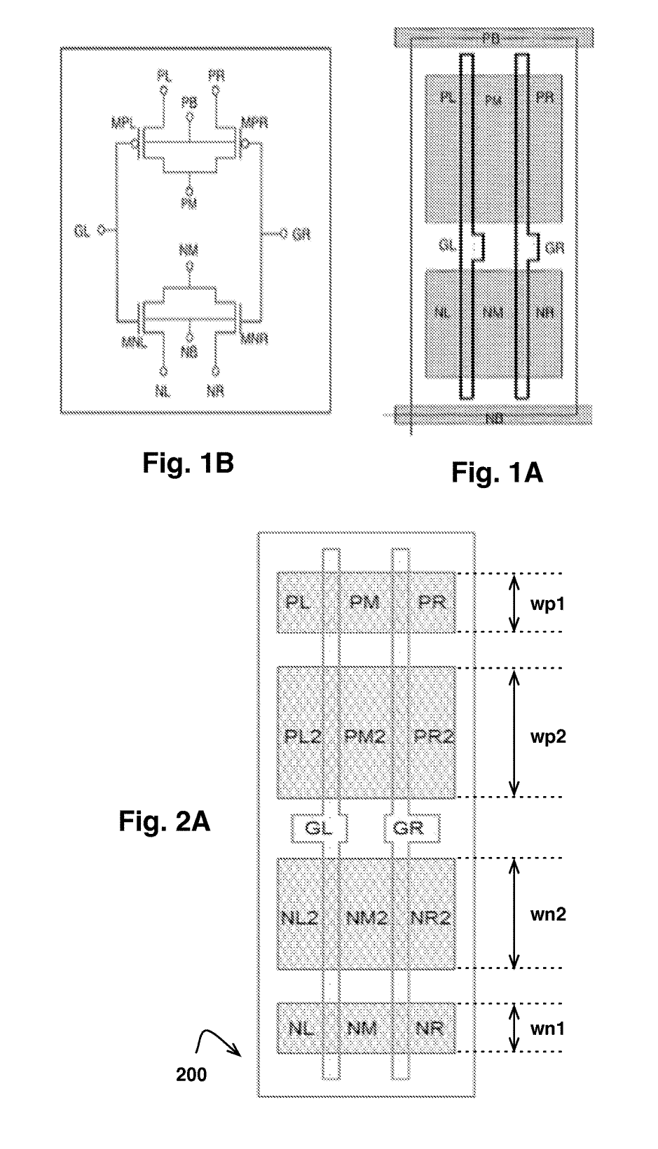

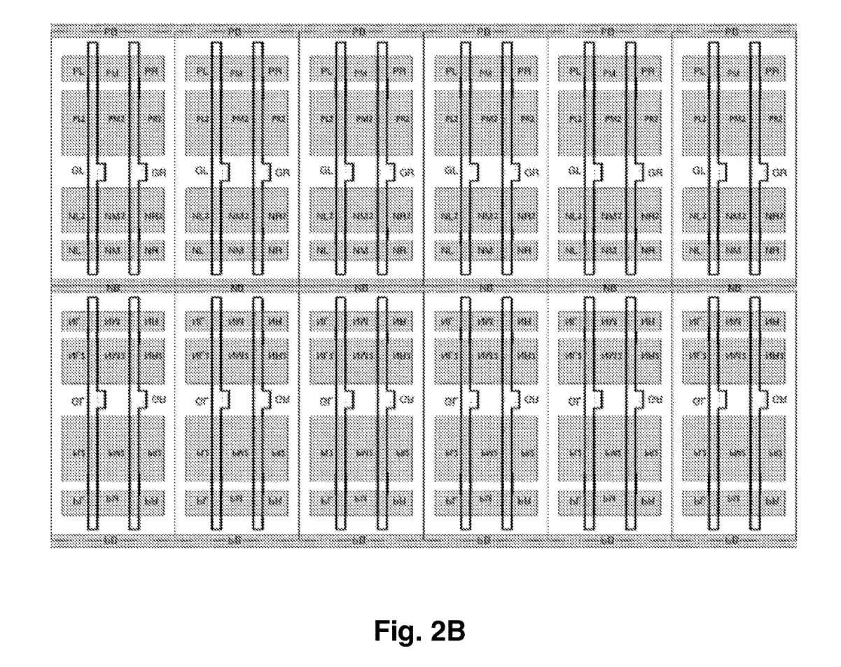

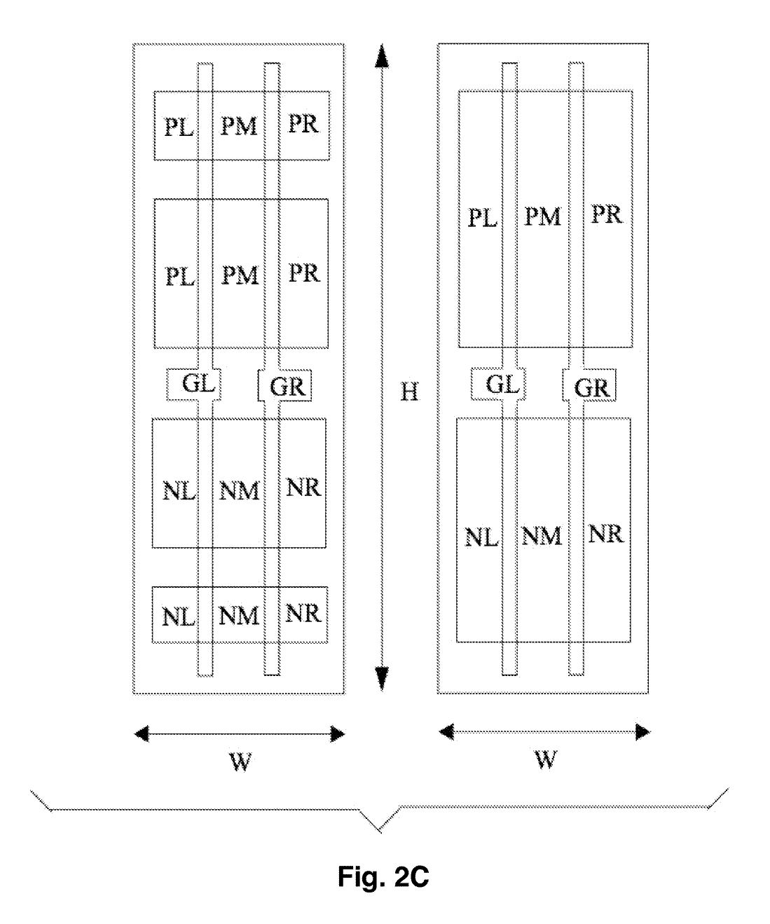

Referring now to FIG. 2A, a diagram is shown of a gate array base cell having an increased number of transistors. As compared to the gate array base cell of FIG. 1A, the gate array base cell 200 of FIG. 2A, in the illustrated embodiment, has twice the number of PMOS transistors (i.e., four PMOS transistors) and twice the number of NMOS transistors (i.e., four NMOS transistors). The PMOS transistors include two smaller transistors PL and PR of a width wp1 and two larger transistors PL2 and PR2 of a width wp2. Similarly, the PMOS transistors include two smaller transistors PL and PR of a width wn1 and two larger transistors PL2 and PR2 of a width wn2.

In one embodiment, such an arrangement of the transistors in metal only programmable base cell architecture provides three different P and N transistor widths per poly gate and may provide nine different combinations transistor widths for P and N for design. For example, the following table shows the poly gate GL and GR of FIG. 2A may have the following combinations of the P and N transistor widths.

| | | 3 Different N transistor widths | | |
|---|---|---|---|---|
| | | wn1 | wn2 | wn1 + wn2 |
| 3 Different | wp1 | wp1, wn1 | wp1, wn2 | wp1, wn1 + wn2 |
| P transistor | wp2 | wp2, wn1 | wp2, wn2 | wp2, wn1 + wn2 |
| widths | wp1 + | wp1 + | wp1 + | wp1 + wp2, |
| | wp2 | wp2, wn1 | wp2, wn2 | wn1 + wn2 |

The table above demonstrates the flexibility of the transistor width for both P and N type transistors of the preferred embodiment for new base cell architecture and these different transistor sizes can be used to create optimum designs for power and performance.

Note further that different numbers of transistors, and different numbers of sizes of transistors, may be used in accordance with gate array base cells of different designs. For example, a base cell might have 12 transistors including six P transistors of three different sizes and six N transistors of three different sizes. Moreover, the number of P transistors and N transistors, and the number of P transistor sizes and N transistors sizes, may not always be the same.

FIG. 2B is a plan diagram of a portion of a gate array using the base cell of FIG. 2A. This portion of the gate array exhibits symmetry about a horizontal center line.

In another embodiment, the gate array base cells of FIG. 2A and FIG. 1A may be the same size, as illustrated in FIG. 2C unlike the base cells with multiple widths transistors in prior arts. The base cell architectures of prior arts may be used for performance and power optimization in cell design however the resulting area would be much larger compared to embodiment of FIG. 2A.

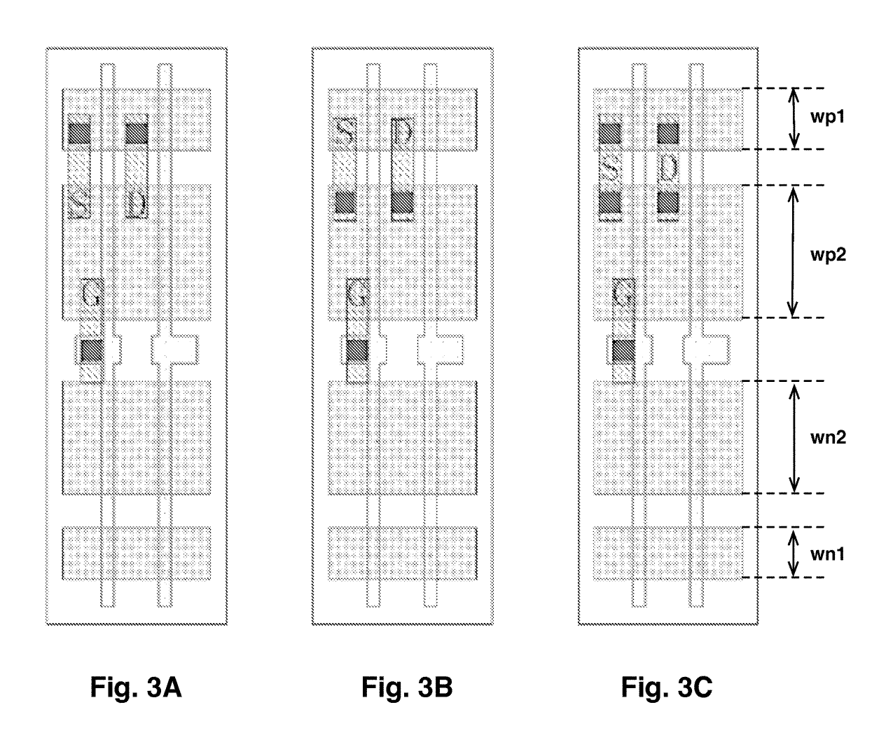

The base cell of FIG. 2A provides flexibility to create transistors of three different sizes, or widths for N and P type transistors and nine different P and N transistor width combinations, according to circuit needs. As shown in FIG. 3A, a small width (wp1) PMOS transistor has a gate electrode G that contacts the gate line GL of FIG. 2A, a source electrode S that contacts the diffusion PL of FIG. 2A, and a drain electrode D that contacts the diffusion PM of FIG. 2A. As shown in FIG. 3B, a medium width (wp2) PMOS transistor has a gate electrode G that contacts the gate line GL of FIG. 2A, a source electrode S that contacts the diffusion PL2 of FIG. 2A, and a drain electrode D that contacts the diffusion PM2 of FIG. 2A. As shown in FIG. 3C, a large width (wp1+wp2) PMOS transistor has a gate electrode G that contacts the gate line GL of FIG. 2A, a source electrode S that contacts both the diffusion PL and the diffusion PL2 of FIG. 2A, and a drain electrode D that contacts both the diffusion PM and the diffusion PM2 of FIG. 2A. In FIG. 3C, small and medium sized PMOS transistors are in effect connected in parallel to realize a larger sized PMOS transistor.

With this transistor width selection flexibility, more optimized circuits can be created, and leakage and switching power may be lowered by using smaller width transistors in certain parts of the circuit.

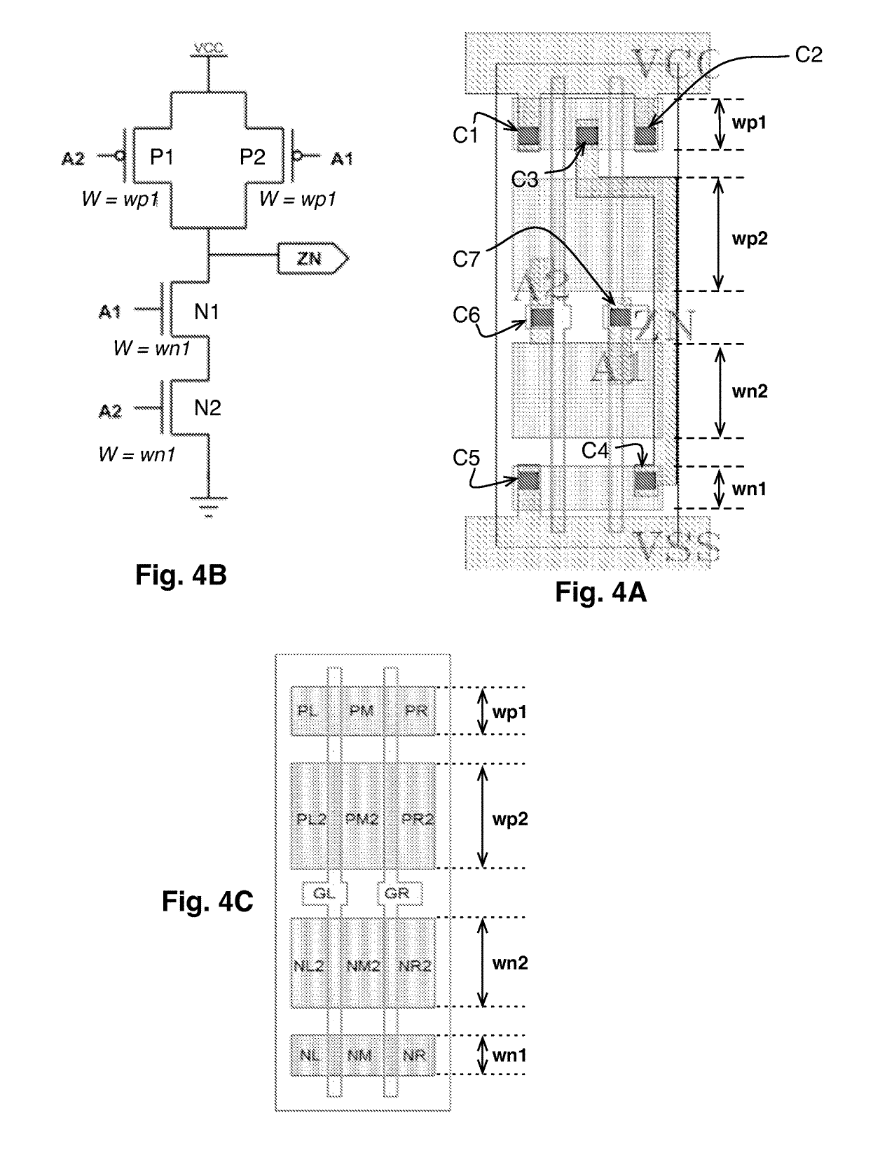

This flexibility may be appreciated with reference to FIGS. 4-6, illustrating NAND gates using different transistors sizes. Referring to FIG. 4A, FIG. 4B and FIG. 4C, a NAND gate is shown in which all small sized transistors are used. To create the NAND function, inputs A1 and A2 are applied to two PMOS transistors P1 and P2 connected in parallel and to two NMOS transistors N1 and N2 connected in series. An inverted output signal ZN is formed at a node where the PMOS portion of the logic gate connected to the NMOS portion of the logic gate.

In the example of FIGS. 4A and 4B, all of the transistors used are small size wp1 and wn1. Hence, in FIG. 4A, the diffusion regions PL2, PM2, PR2 and NL2, NM2, NR2 are not contacted. Rather, contacts C1 and C2 connect the transistors P1 and P2 to VCC. The contact C3 connects a common point of the transistors P1 and P2 to the transistor N2 by means of a trace ZN that forms the output signal of the NAND gate and a contact C4. A contact C5 connects the transistor N1 to VSS. Finally, contacts C6 and C7 connect input signals A1 and A2 to the right gate line GL, shared by the transistors P1 and N1, and the left gate line GR, shared by the transistors P2 and N2.

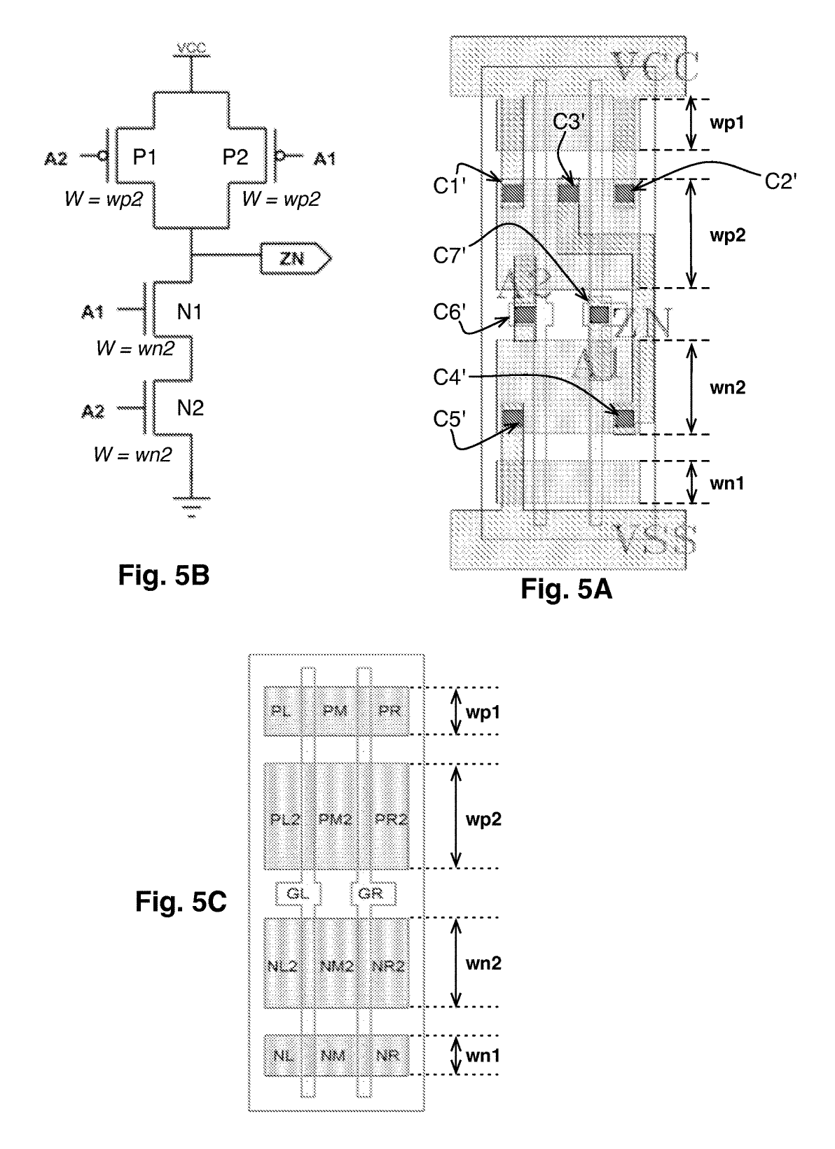

In the example of FIGS. 5A and 5B, all of the transistors used are medium size wp2 and wn2. Hence, in FIG. 5A, contacts C1′, C2′ and C3′ contact the diffusion areas PL2, PM2 and PR2, not previously contacted, instead of the diffusion areas PL, PM and PR. Similarly, the contacts C4′ and C5′ contact the diffusion areas NR2 and NL2, not previously contacted, instead of the diffusion areas NR and NL. FIG. 5C is a plan diagram of the base cell.

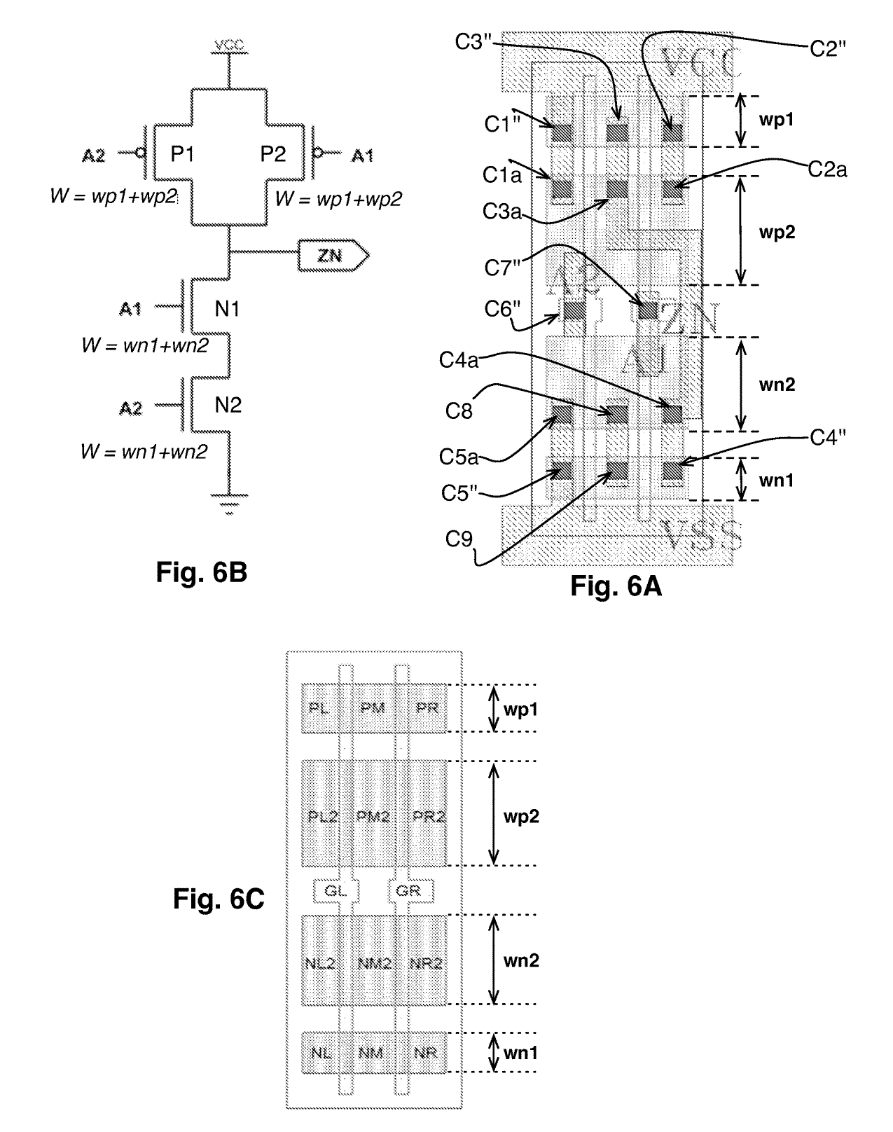

In the example of FIGS. 6A and 6B, all of the transistors are large sizes which are wp1+wp2 for P and wn1+wn2 for N. Hence, in FIG. 6A, contacts C1″, C2″ and C3″ contact the diffusion areas PL, PM and PR, and in addition, contacts C1a, C2a and C3a contact the diffusion areas PL2, PM2 and PR2 which the connection provides effective P transistor width of wp1+wp2. Similarly, the contacts C4″ and C5″ contact the diffusion areas NR and NL, and in addition, contacts C4a and C5a contact the diffusion areas NR2 and NL2. Additional contacts C8 and C9 are used to connect the diffusion area NM and NM2 which these connection provides effective N transistor with of wn1+wn2. FIG. 6C is a plan diagram of the base cell.

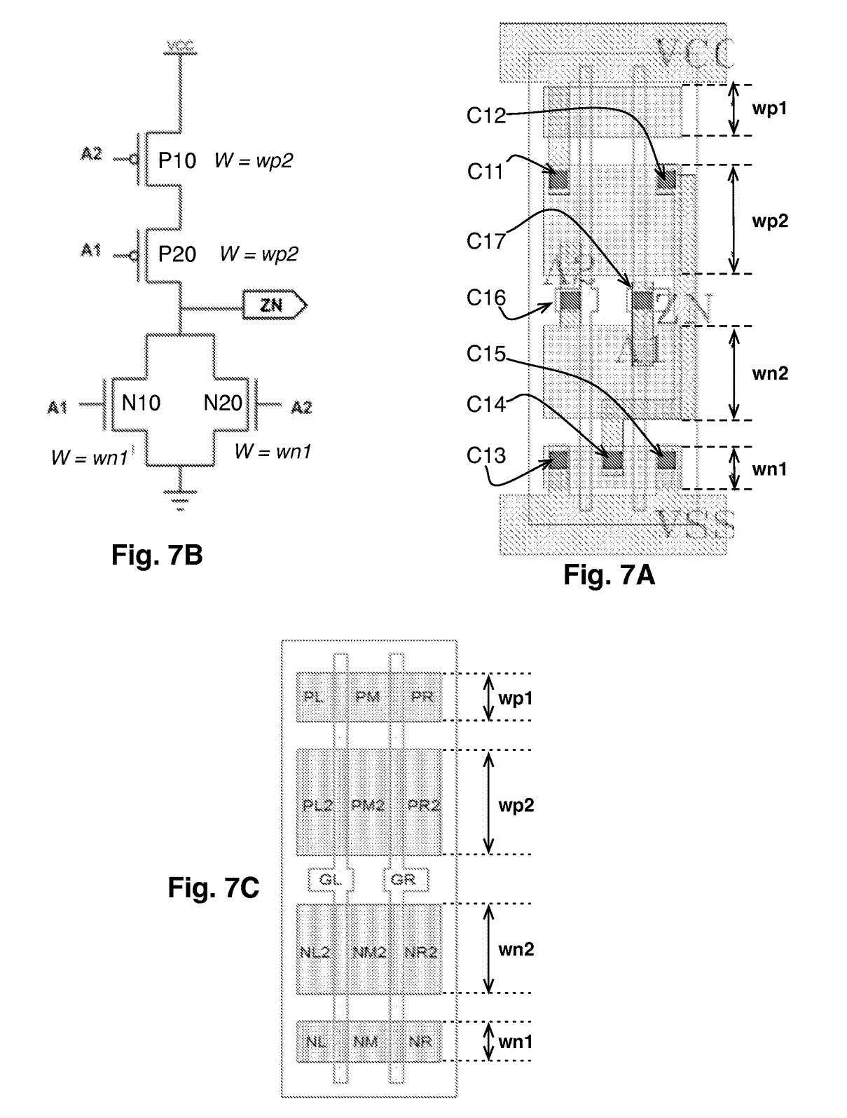

Referring to FIGS. 7A and 7B, an example is shown of a NOR gate in which the P transistors P10 and P20 are medium size transistors wp2 and the N transistors N10 and N20 are small size transistors wn1. The topology of a NOR gate is opposite that of a NAND gate, with the P transistors being connected in series and the N transistors being connected in parallel. The contacts C11 and C12 contact the diffusion regions PL2 and PR2. The contacts C13, C14 and C15 contact the diffusion regions NR, NM and NL. The contacts C16 and C17 contact the gate lines. Using all medium width (wp2) PMOS transistors and two small width (wn1) NMOS transistors in this example creates more balanced rise and fall times of the output drive.

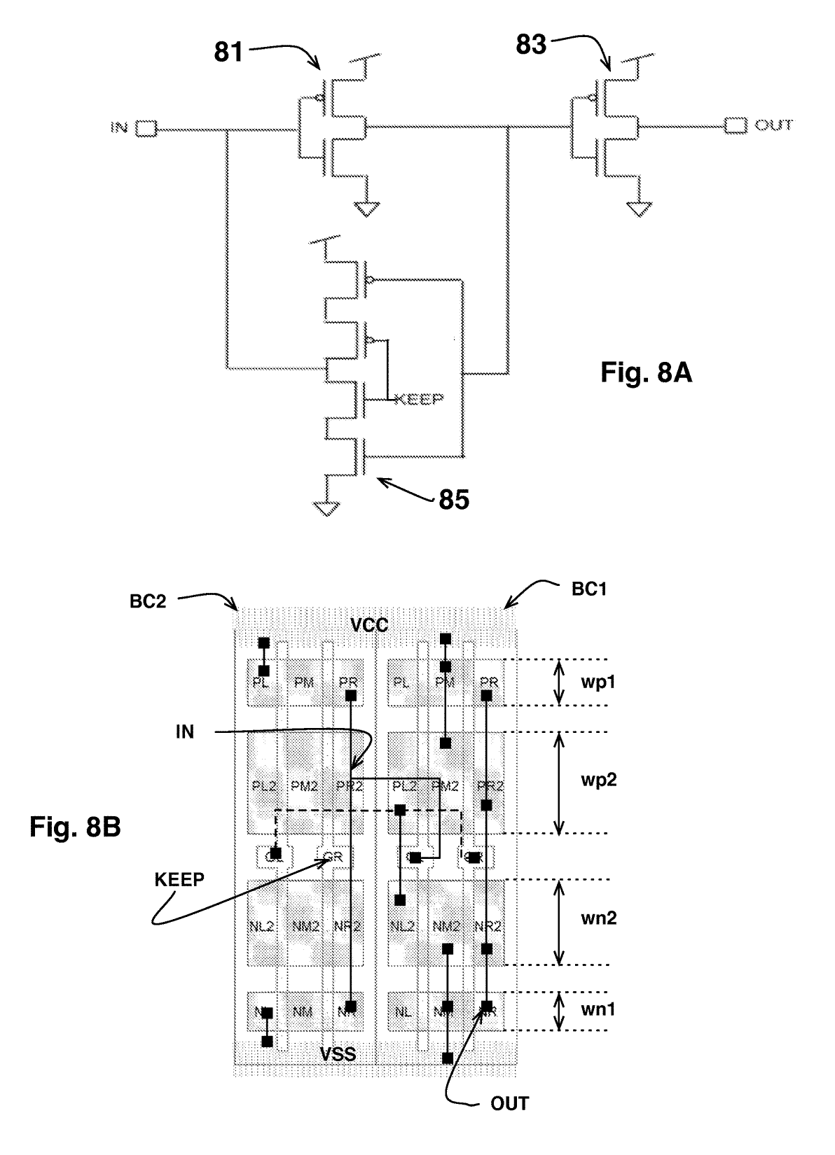

A circuit may combine small (wp1 and wn1), medium (wp2 and wn2) and large transistors (wp1+wp2 and wn1+wn2). An example of one such circuit is a latch circuit, shown in FIG. 8A may illustrate different combination of transistor widths for optimum circuit design for power and performance. The FIG. 8B is an example layout connection diagram for latch circuit shown in FIG. 8A. The FIG. 8B illustrates two adjacent base cell 200 of FIG. 2A, BC1 and BC2 may be used create the latch circuit. The latch circuit includes a feed-forward inverter 81 that may include transistors PL2 and NL2 from base cell BC1, an output driver 83 that may include transistors PR+PR2 and NR2+NR1 from base cell BC1, and a feedback tri-state inverter 85 that includes transistors PR and PL, and NR and NL from base cell BC2. When the input signal KEEP is true, the input value is latched and kept and provided as the output signal. When KEEP is false, the input value is not latched; the output signal varies as the input signal.

In order to obtain lower dynamic and static power and potentially better performance, the effective width per transistor for the feedback tri-state inverter 85 is small (wp1 and wn1) for both PMOS and NMOS transistors. Meanwhile, the effective width per transistor for the feed-forward inverter 81 is medium for both PMOS and NMOS transistors (wp2 and wn2). Finally, the effective width per transistor for the driver 83 is large for both PMOS and NMOS transistors (wp1+wp2 and wn1+wn2). The FIGS. 8A and 8B illustrates the embodiments of the having same base cell size compared to traditional gate array base cell of FIG. 1A but may provide different transistor width for power and performance optimization during design.

A comparison of the base cell of FIG. 2A as compared to the base cell of FIG. 1A is shown in the following table for various attributes:

| | FIG. 2A Versus FIG. lA |
|---|---|
| Area | Same (0%) |
| Leakage Power | upto −40% reduction |
| Active Power | upto −30% reduction |
| Performance | upto +10% improvement |

As seen in this table, active and leakage power may be made significantly smaller and performance can be also improved, by application of the foregoing teachings.

Unless otherwise defined, words of approximation as used herein shall mean plus or minus ten percent of nominal value.

It will be apparent to those skilled in the art that the present invention may be embodied in other specific forms without departing from the spirit or essential character thereof. The described embodiments are therefore intended in all respects to be illustrative and not restrictive. The scope of the invention is indicated by the appended claims, not the foregoing description, and all changes that come within the meaning and range of equivalents thereof are intended to be embraced therein.

What is claimed is:

1. A base cell in a metal programmable area of an integrated circuit, said base cell comprising:
two same or different sizes of N-channel transistor diffusion regions;
two same or different sizes of P-channel transistor diffusion regions; and
two polysilicon gate electrodes for defining N-channel transistors and P-channel transistors, overlying the the diffusion regions so as to form eight transistors, including four same or different sizes of N-channel transistors in accordance with the same or different sizes of N-channel transistor diffusion regions, and four same or different sizes of P-channel transistors in accordance with the same or different sizes of P-channel diffusion regions, wherein transistor size corresponds to channel width within said base cell;
wherein said base cell is one of a plurality of base cells located within the metal-programmable area.

2. The apparatus of claim 1, wherein each polysilicon gate electrode defines four transistors.

3. The apparatus of claim 2, wherein the four transistors consist of two N-channel transistors and two P-channel transistors.

4. The apparatus of claim 1, wherein the two N-channel transistor diffusion regions are different sizes.

5. The apparatus of claim 1, wherein the two P-channel transistor diffusion regions are different sizes.

6. The apparatus of claim 1, wherein the two N-channel transistor diffusion regions are different sizes, and the two P-channel transistor diffusion regions are different sizes.

7. The apparatus of claim 6, comprising customization circuitry comprising one or more metal layers for selectively interconnecting the transistors of the base cell to form transistor circuits that function as transistors of a further size, different than sizes of any of the N-transistors and any of the P-transistors.

8. The apparatus of claim 6, wherein the base cell provides for three different widths of N-channel transistors and three different widths of P-channel transistors.

9. The apparatus of claim 1, wherein a two-dimensional array of said base cells occupies all of the metal-programmable area.

10. The apparatus of claim 1, wherein the base cell has the same area as a prior-generation base cell consisting of four transistors, including two P transistors of equal width and two N transistors of equal width, such that backward compatibility is achieved.

11. An integrated circuit comprising:
a metal-programmable area;
within the metal programmable area, a gate array layer comprising a two-dimensional array of base cells, each base cell within the metal programmable area being the same and comprising:
a plurality of gate electrodes and a plurality of groups of transistors, each group of transistors being coupled to one of the plurality of gate electrodes;
wherein each of the group of transistors comprises a plurality of P transistors of a first number of different widths and a plurality of N transistors of second number of different widths;
wherein each base cell has the same area as a prior-generation base cell consisting of four transistors, including two P transistors of equal width and two N transistors of equal width, such that backward compatibility is achieved.

12. An integrated circuit comprising:
a metal-programmable area;
a gate array layer comprising a two-dimensional array of base cells that occupies the metal programmable area, each base cell comprising a plurality of gate electrodes each coupled to a plurality of transistors of different conductivity types and different sizes.

13. The apparatus of claim 12, comprising customization circuitry comprising one or more metal layers for selectively interconnecting the transistors of the base cells to form transistor circuits that function as transistors of a further size.

14. The apparatus of claim 12, wherein the plurality of transistors comprises at least two N-type transistors of different sizes and at least two P-type transistors of different sizes.

15. The apparatus of claim 12, wherein the plurality of transistors comprises at least four N-type transistors of at least two different sizes and at least four P-type transistors of at least two different sizes.

16. The apparatus of claim 12, wherein the plurality of transistors comprises four N-type transistors of two different sizes and four P-type transistors of two different sizes.

17. A method of using one or more metal layers to customize an integrated circuit having a metal-programmable area comprising a gate array layer comprising a two-dimensional array of base cells that occupies the metal-programmable area, each base cell comprising a plurality of gate electrodes and a plurality of transistors of different conductivity types and different sizes, the method comprising:
interconnecting the plurality of gate electrodes and the plurality of transistors such that each of the plurality of gate electrodes is coupled to a plurality of transistors of different conductivity types and different sizes; and
interconnecting transistors of different sizes in parallel to form transistor circuits that function as transistors of a further size.

18. The method of claim 17, wherein the plurality of transistors comprises at least two N-type transistors of different sizes and at least two P-type transistors of different sizes.

19. The method of claim 17, wherein the plurality of transistors comprises at least four N-type transistors of at least two different sizes and at least four P-type transistors of at least two different sizes.

20. The apparatus of claim 12, wherein the two-dimensional array of base cells occupies all of the metal-programmable area.

21. An integrated circuit comprising:
a metal-programmable area;
within the metal programmable area, a gate array layer comprising a two-dimensional array of base cells, each base cell comprising:
a plurality of gate electrodes and a plurality of groups of transistors, each group of transistors being coupled to one of the plurality of gate electrodes;
wherein each of the group of transistors comprises a plurality of P transistors of a first number of different widths and a plurality of N transistors of second number of different widths.

22. The apparatus of claim 21, wherein the first number and the second number are both two.

23. The apparatus of claim 22, comprising a metal programmable layer for interconnecting a transistor of a first width and a transistors of a second different width to form a transistor circuit equivalent to a transistor having a third width equal to a sum of the first width and the second width.
